(19) United States
(12) Patent Application Publication
(10) Pub. No.: US 2004/0185580 A1
(43) Pub. Date: Sep. 23, 2004

(54) Method for dicing semiconductor wafer

(76) Inventor: Seok Goh, Cheonan-si (KR)

Correspondence Address: HARNESS, DICKEY & PIERCE, P.L.C., P.O. BOX 8910, RESTON, VA, 20195, US

(21) Appl. No.: 10/805,212

(22) Filed: Mar. 22, 2004

(30) Foreign Application Priority Data
Mar. 22, 2003 (KR) 2003-17968

(51) Int. Cl. H01L 21/00

(52) U.S. Cl. 438/5; 438/462; 438/460

(57) ABSTRACT

A method for dicing semiconductor wafers is provided in which data present on the primary surface of the semiconductor wafers is recognized and used to controlling the cutting operation. The combination of the controller and the cutting means allows for the cutting of complex and non-linear shapes and allows for the combination of more than one semiconductor chip edge profile on a semiconductor wafer. The cutting means is preferably a laser or other cutting device capable of cutting fine patterns without causing undue damage to the semiconductor wafer or the resulting semiconductor chips. The more complex profiles of the semiconductor chips that may be produced with this method may, in turn, be utilized to improve the density within semiconductor device packages and/or on mounting substrates such as a printed circuit boards. The present invention can, therefore, improve space utilization, reduce fabrication expenses, reduce processing time and simplify package manufacture.

### CROSS-REFERENCE TO RELATED APPLICATIONS

This U.S. non-provisional application claims priority under 35 U.S.C. § 119 of Korean Patent Application No. 2003-17968, which was filed Mar. 22, 2003, the entire contents of which are incorporated herein by reference.

### BACKGROUND OF THE INVENTION

1. Field of the Invention

The present invention relates to a method for manufacturing a semiconductor device and, more particularly, to an improved method for dicing a semiconductor wafer to separate individual semiconductor chips.

2. Description of the Related Art

Generally, wafer dicing processes are used to dice a completed wafer and separate the semiconductor wafer into a plurality of individual semiconductor chips. The wafer dicing process is typically performed between the completion of the wafer fabrication process and the initiation of the semiconductor device assembly process. Conventional wafer dicing processes dice the completed semiconductor wafer by moving a rotating saw blade along scribe lines provided on the semiconductor wafer between adjacent semiconductor chips. The dicing operation may be controlled by a control program into which data specific to the semiconductor wafer has been input.

As a result of the physical characteristics of the conventional sawing blades and the procedural limitations of the uniform dicing operation by the control program, the semiconductor chips produced from a single semiconductor wafer typically have only simple shapes, typically rectangular, and are generally of uniform size. The conventional wafer dicing methods and apparatus are not, therefore, suitable for meeting the increasing demand for semiconductor chips having more complex configurations or separating a variety of shapes from a single semiconductor wafer. Further, the use of conventional sawing blades has been associated with certain characteristic types of damage to the semiconductor chips due to shock, frictional heating and chipping associated with the mechanical contact between the semiconductor wafer and the sawing blade.

In order to address certain of these problems, lasers have been utilized as an alternative to conventional sawing blades in wafer dicing processes as disclosed in, for example, Korean Patent Publication Nos. 1998-084225 and 1998-067184. As disclosed in these Korean Patent Publications, lasers are presented as a means for suppressing or reducing the characteristic damage to the semiconductor chips associated with the conventional sawing operations in the production of traditional, rectangular and uniformly-sized semiconductor chips.

FIG. 1 is a flow chart illustrating a sequence of events associated with a conventional wafer dicing method. FIG. 2 is a perspective view of a dicing operation according to a conventional wafer dicing method. FIG. 3 is a perspective view of individual semiconductor chips according to a conventional wafer dicing method. FIG. 4 is a view of a stacked semiconductor chip package including two semiconductor chips produced according to a conventional wafer dicing method.

FIG. 1 illustrates the sequence of steps in a conventional wafer dicing method. As shown in FIG. 1, the method comprises aligning a semiconductor wafer 10 relative to the dicing device (step A) and energizing the dicing device (step B). A dicing operation is then conducted under the control of a control program into which data on the semiconductor wafer 10 being diced has been input (step C). The semiconductor wafer 10 is typically aligned on a vacuum chuck or other holding device with reference to one or more distinct regions provided on the circumference, typically a major “flat” and possibly one or more minor “flats.”

A sawing blade 12 is then activated and moved sequentially along the various kerf regions or scribe lines S arranged between adjacent semiconductor chips to separate the individual chips. The movement of the sawing blade 12 relative to the semiconductor wafer 10 is determined by the control program, into which control data, such as the orientation and spacing of the scribe lines S, has already been input. As illustrated in FIG. 3, upon completion of the dicing operation, the semiconductor wafer will be transformed into an array of individual semiconductor chips 14 of uniform rectangular configuration. The individual semiconductor chips may then be separated and incorporated into a semiconductor device package.

As illustrated in FIG. 4, two semiconductor chips 21 and 23 having the conventional rectangular configuration may be arranged in a stacked configuration during the fabrication of a semiconductor chip-set type package. As will be appreciated, the two semiconductor chips, rather than being stacked, may be arranged in generally planar side-by-side configuration. In both of these configurations, however, the dimensions of the resulting semiconductor chip-set type package are somewhat limited and may require a package having a height or a surface area in excess of a desired range. Further, even in those instances in which the dimensions of the resulting package are acceptable, the limited range of shapes resulting from the generally uniform shape of the semiconductor chips may result in inefficient space utilization on a mounting substrate.

### SUMMARY OF THE INVENTION

An exemplary embodiment of the present invention is directed to a method for dicing a semiconductor wafer that will provide for the fabrication of semiconductor chips having more complex configurations and for the separation of multiple semiconductor chip configurations from a single semiconductor wafer. Exemplary embodiments of the invention may comprise recognizing data on the shapes of the semiconductor chips, operating a dicing device for dicing the semiconductor wafer, and controlling the dicing device based on the data to perform a dicing operation on the semiconductor wafer.

According to exemplary embodiments of the invention, a laser or other cutting means capable of forming fine patterns will be incorporated in the dicing device as the dicing means, thereby easing the configuration limitations associated with the use of a conventional sawing blade as well as reducing damage to the semiconductor wafer. Utilizing an exemplary embodiment of the invention, therefore, a single semiconductor wafer can be diced into semiconductor chips having a variety of shapes that may, in turn, be utilized in the fabrication of semiconductor packages configured to improve space utilization on a mounting substrate.

### BRIEF DESCRIPTION OF THE DRAWINGS

These and other features and advantages of the exemplary embodiments of the present invention will be readily understood with reference to the following detailed description thereof provided in conjunction with the accompanying drawings, wherein like reference numerals designate like structural elements, and in which:

FIG. 1 is a flow chart of a conventional wafer dicing method;

FIG. 2 is a perspective view of a dicing operation according to an exemplary embodiment of the conventional wafer dicing method;

FIG. 3 is a perspective view of individual semiconductor chips according to an exemplary embodiment of the conventional wafer dicing method;

FIG. 4 is a view of a semiconductor chip package having the semiconductor chips according to an exemplary embodiment of the conventional wafer dicing method;

FIG. 5 is a flow chart of a method for dicing a semiconductor wafer according to an exemplary embodiment of the present invention;

FIG. 6 is a perspective view of a dicing operation according to an exemplary embodiment of the present invention;

FIG. 7 is a plane view of semiconductor chips having a variety of shapes according to an exemplary embodiment of the present invention; and

FIG. 8 is a view of a semiconductor chip package having the semiconductor chips according to an exemplary embodiment of the present invention.

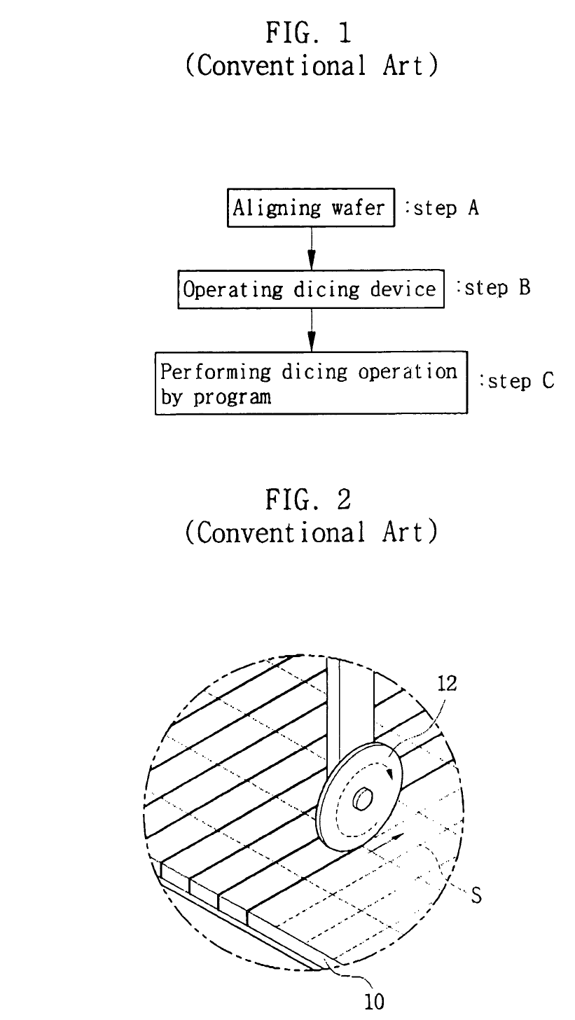

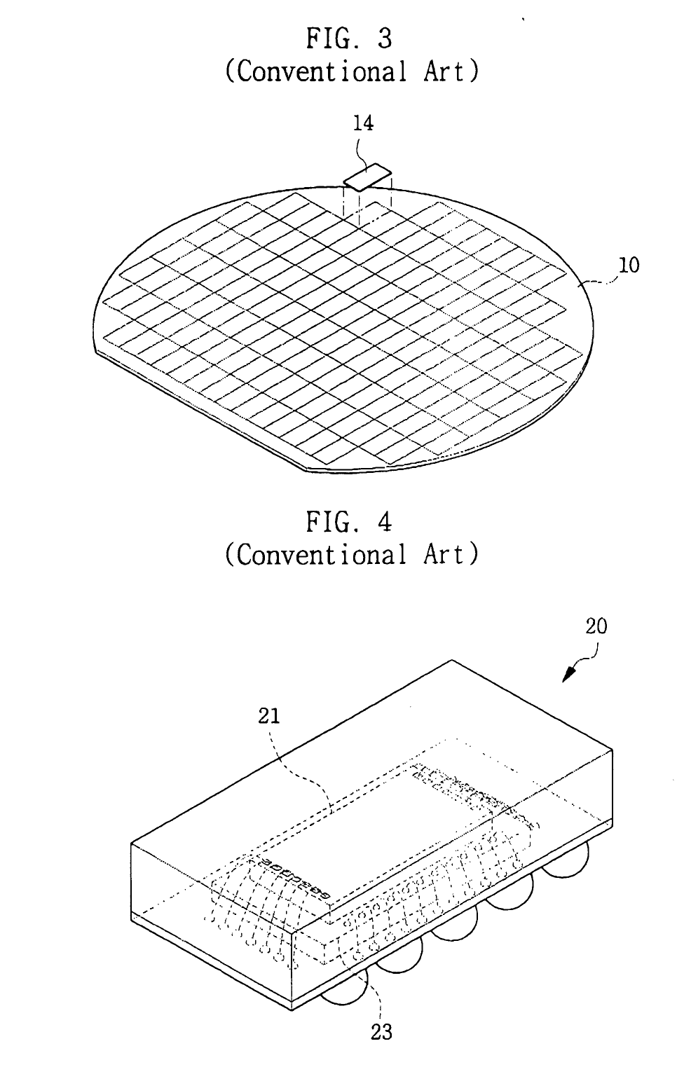

These drawings have been provided to assist in the understanding of the exemplary embodiments of the invention as described in more detail below and should not be construed as unduly limiting the invention. In particular, the relative spacing, sizing and dimensions of the various elements illustrated in the drawings are not drawn to scale and may have been exaggerated, reduced or otherwise modified for the purpose of improved clarity. Those of ordinary skill in the art will also appreciate that certain elements commonly utilized in the dicing of semiconductor wafers including, for example, vacuum chucks, blow-off devices, shrouding, etc., have been omitted simply to improve the clarity and reduce the number of drawings.,

### DETAILED DESCRIPTION OF THE EXEMPLARY EMBODIMENTS

The present invention will now be described more fully hereinafter with reference to the accompanying drawings, in which exemplary embodiments of the invention are shown. The exemplary embodiments of the invention may, however, be embodied in different forms and should not be construed as limited to the exemplary embodiments set forth herein. Rather, these exemplary embodiments are provided so that this disclosure will be thorough and complete, and will fully convey the scope of the invention to those skilled in the art. It will be understood that the depicted elements may be simplified and/or merely exemplary, and are not necessarily drawn to scale.

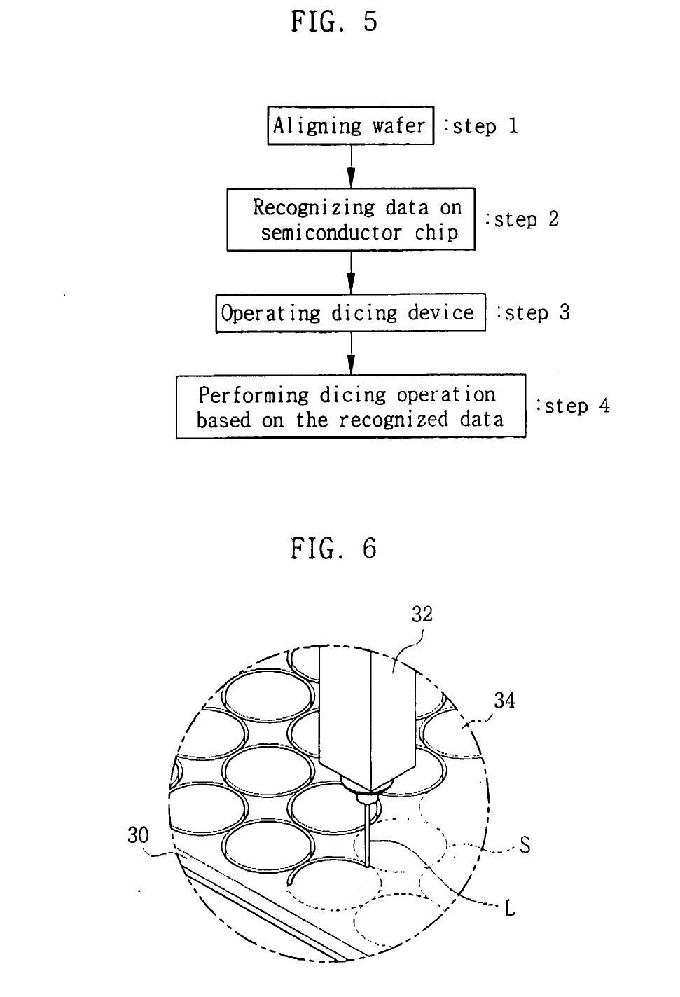

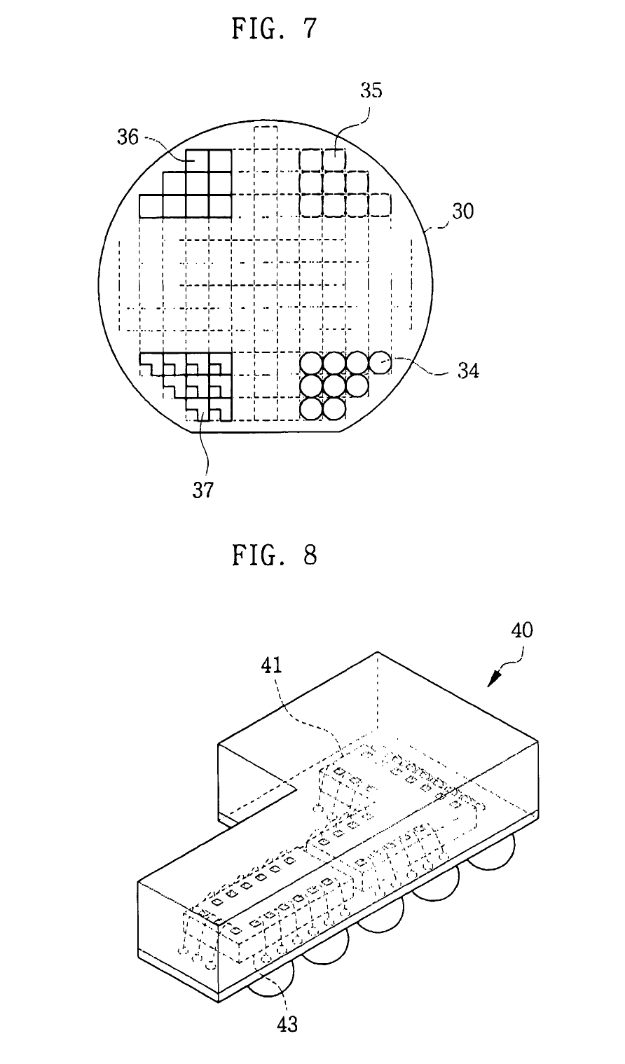

FIG. 5 is a flow chart outlining a method for dicing a semiconductor wafer according to an exemplary embodiment of the present invention. FIG. 6 is a perspective view of a dicing operation according to an exemplary embodiment of the present invention. FIG. 7 is a plan view of a semiconductor wafer incorporating semiconductor chips having a variety of shapes according to an exemplary embodiment of the present invention. FIG. 8 is a view of a semiconductor chip-set type package incorporating two semiconductor chips according to an exemplary embodiment of the present invention.

As illustrated in FIGS. 5 and 6, a semiconductor wafer 30 is first aligned relative to the dicing apparatus. Data corresponding to both the types and arrangement of the various semiconductor chip shapes formed on the semiconductor wafer 30 is recognized. This recognition may be achieved using one or more methods including, for example, reading wafer ID information from a portion of the wafer surface, reading information from the wafer carrier, ID information input by an operator and/or optical pattern recognition.

A cutting device, such as the laser dicing device 32 in FIG. 6 generating laser beam (L) is then activated. The dicing operation is performed by controlling the relative movement of the semiconductor wafer 30 and the cutting device based on the semiconductor wafer-specific data provided to or recognized by the controller. The cutting device removes the full thickness of the semiconductor wafer material from at least a portion of the width of the scribe lines surrounding the semiconductor chips that are to be separated. The duration of the dicing operation may be reduced by only removing the scribe lines surrounding known good die. The known good die may be identified to the controller using various methods, including for example retrieval of test data associated the recognized wafer data and/or optical indicia of the semiconductor chip functionality such as an ink dot on a failing semiconductor chip that can be recognized by or identified to the controller.

According to an exemplary embodiment of the, the semiconductor wafer 30 is first aligned relative to the dicing device, typically by using a distinct portion of the semiconductor wafer periphery such as a flat zone. Data corresponding to the arrangement and configuration of the semiconductor chips including, for example, the shapes of the semiconductor chips and position and direction of scribe lines (S) may then be recognized or identified using a system for reading the surface of the semiconductor wafer 30 using, for example, a computer vision system or a scanning system. The data read from the semiconductor wafer surface, particularly the identification of a specific semiconductor wafer, may also be used by the controller to access more detailed data. The accessed data may relate to the particular semiconductor wafer being read, such as parametric or functional test data, or more general data common to each similarly processed semiconductor wafer, such as the configuration of the semiconductor chips common to all such wafers.

The laser dicing device 32 using laser beam (L) may then be activated and moved relative to the semiconductor wafer 30 based on the recognized data and/or retrieved data to remove the desired scribe line material and thereby separate the individual semiconductor chips. As illustrated in FIG. 7, a single semiconductor wafer may include semiconductor chips having a variety of desired shapes including, for example a circular type 34, a rounded edge type 35, a rectangular type 36 or a more complex type such as the stepped type 37.

As illustrated in FIG. 8, semiconductor chips 41, a stepped type, and 43, a more typical rectangular type, may be combined in a single chip-set type semiconductor chip package 40. By increasing the complexity of the semiconductor chips that can be successfully separated from a semiconductor wafer, the exemplary embodiments of the present invention provide for a corresponding increase in the configuration of semiconductor chip packages that may be fabricated. By providing for semiconductor chip packages that are not generally limited to a simple rectangular periphery, the exemplary embodiments of the present invention may be used to improve the mounting density on a mounting substrate, reduce the size of the semiconductor chip package itself and/or improve space utilization.

In accordance with exemplary embodiments of the present invention, a method for dicing a semiconductor wafer may comprise recognizing data or other identifying indicia on the surface of a semiconductor wafer that allows data corresponding to the various shapes and layout of the semiconductor chips provided on the semiconductor wafer to be retrieved. Further, based on the data recognized or retrieved, the exemplary embodiments of the present invention will control the operation of a dicing device for dicing the semiconductor wafer into the desired individual semiconductor devices.

Further, the exemplary methods for dicing a semiconductor wafer according to the present invention will employ laser or other cutting means capable of cutting fine patterns as a dicing means, thereby avoiding the limitations inherent in the use of a conventional sawing blade including damage to the semiconductor wafer and allow the separation of semiconductor chips having a variety of shapes and/or more complex non-rectangular shapes from a semiconductor wafer. The more complex non-rectangular semiconductor chips may, in turn, be utilized to improve the packing density within a single semiconductor package and/or provide semiconductor packages that may be used to improve the space utilization on a mounting substrate. Additional benefits may include reductions in processing time and simplified processes for semiconductor package manufacture.

Although the exemplary embodiments of the present invention have been described in detail hereinabove, it should be understood that many variations and/or modifications of the basic inventive concepts herein taught, which may appear to those skilled in the art, will still fall within the spirit and scope of the exemplary embodiments of the present invention as defined in the appended claims.

What is claimed is:

1. A method for dicing a semiconductor wafer having a plurality of semiconductor chips fabricated on a primary surface comprising:
reading data from the primary surface;
controlling the movement of a cutting device relative to the primary surface of the semiconductor wafer based on the data; and
operating the cutting device whereby portions of the semiconductor wafer between adjacent semiconductor chips are removed to separate individual semiconductor chips.

2. A method for dicing a semiconductor wafer according to claim 1, further comprising:
aligning the semiconductor wafer relative to the cutting device.

3. A method for dicing a semiconductor wafer according to claim 1, wherein:
the cutting device includes a laser.

4. A method for dicing a semiconductor wafer according to claim 1, further comprising:
retrieving additional data corresponding to the data read from the primary surface.

5. A method for dicing a semiconductor wafer according to claim 4, wherein:
the additional data includes parametric test data or functional test data corresponding to one or more of the semiconductor chips.

6. A method for dicing a semiconductor wafer according to claim 1, wherein:
reading data from the primary surface includes a method selected from a group consisting of optical scanning of a majority of the primary surface, optical scanning of predetermined regions on the primary surface, optical scanning of encoded regions, laser scanning of a majority of the primary surface, laser scanning of predetermined regions on the primary surface, laser scanning of encoded regions and laser scanning of barcode regions.

7. A method for dicing a semiconductor wafer according to claim 1, wherein:
the plurality of semiconductor chips arranged on the primary surface include a first group having a first edge profile and a second group having a second edge profile, wherein the first edge profile is distinct from the second edge profile.

8. A method for dicing a semiconductor wafer according to claim 7, wherein:
at least one of the edge profiles includes a stepped region.

9. A method for dicing a semiconductor wafer according to claim 7, wherein:
at least one of the edge profiles includes a curved region.

10. A method for dicing a semiconductor wafer according to claim 7, wherein:
at least one of the edge profiles includes a concave region.

11. A method for dicing a semiconductor wafer according to claim 1, wherein:
the plurality of semiconductor chips arranged on the primary surface have a uniform edge profile.

12. A method for dicing a semiconductor wafer according to claim 11, wherein:
the edge profile includes a stepped region.

13. A method for dicing a semiconductor wafer according to claim 11, wherein:
the edge profiles includes a curved region.

14. A method for dicing a semiconductor wafer according to claim 11, wherein:
the edge profiles includes a concave region.

15. A method for dicing a semiconductor wafer according to claim 1, wherein:
the data read from the primary surface is used to identify known good die; and
only those portions of the semiconductor wafer surrounding known good die are removed.

16. A method for dicing a semiconductor wafer having a plurality of semiconductor chips fabricated on a primary surface comprising:
reading data from the primary surface;
controlling the movement of a cutting device relative to the primary surface of the semiconductor wafer based on the data; and
operating the cutting device whereby portions of the semiconductor wafer between adjacent semiconductor chips are removed to separate a first semiconductor chip having a first edge profile and a second semiconductor chip having a second edge profile, wherein the first and second edge profiles are complementary whereby the first and second semiconductor chips may be incorporated in a chip set package to improve space utilization within the chip set package.
